(19) United States
(12) Patent Application Publication
(10) Pub. No.: US 2026/0362818 A1
(43) Pub. Date: Nov. 12, 2026

(54) SEMICONDUCTOR DEVICE WITH ELECTROSTATIC DISCHARGE PROTECTION

(71) Applicant: Taiwan Semiconductor Manufacturing Company, LTD., Hsinchu (TW)

(72) Inventors: Lin-Yu Huang, Hsinchu (TW); Shih-Fan Chen, Hsinchu (TW); Sheng-Fu Hsu, Hsinchu (TW)

(21) Appl. No.: 19/203,353

(22) Filed: May 9, 2025

(51) Int. Cl. H10D 89/60; H10D 30/01; H10D 62/10; H10D 62/17; H10D 62/60; H10D 84/83

(52) U.S. Cl. CPC H10D 89/931; H10D 30/027; H10D 62/124; H10D 62/299; H10D 62/60; H10D 84/83125

(57) ABSTRACT

To form a slotted well, a mask comprising a plurality of mutually parallel masking strips is disposed on a base semiconductor doped at a first doping type, and dopant implantation of the first doping type is performed through the well slot mask, with implantation being blocked from slots of the base semiconductor located underneath the masking strips. A transistor or other semiconductor device is formed in the slotted well. In a transistor example, the semiconductor device is formed by forming source and drain regions of a second doping type opposite the first doping type in the slotted well. A semiconductor device includes a transistor disposed in a slotted well with slots having doping a first doping level and slot spaces between the slots having doping of a same type as the slots at a second doping level greater than the first doping level.

### BACKGROUND

The following relates to the semiconductor device arts, field effect transistor arts, semiconductor fabrication arts, electrostatic discharge (ESD) protection arts, and related arts.

Devices such as metal-oxide-semiconductor (MOS) field effect transistor (FET) devices (i.e., MOSFETs) can be prone to be damaged by electrostatic discharge (ESD). MOSFETs used in input and output (I/O) of an integrated circuit (IC) can be likely contact points for an ESD. For example, a person who has accumulated an electrostatic charge can be discharged to the MOSFET as a large transient electric current (colloquially called a “zap” or “shock” event), and this large transient electric current can damage the MOSFET. Other types of semiconductor devices such as diodes can also be prone to ESD damage. Also, the source of the electrostatic discharge can more generally be any person or object capable of accumulating an electrostatic charge.

In electronic device design, a Human Body Model (HBM) may be employed to assess the resistance of a semiconductor device to ESD damage. In an experimental setting, an HBM test circuit may be employed, for example comprising an RC circuit with a high voltage source and one or more switches to simulate a transient ESD event from contact with a charged person on a device-under-test (DUT). Some ICs may include one or more dedicated ESD MOSFETs designed for high voltage to provide ESD protection.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a cut view of a semiconductor device with a slot well to improve resistance to damage from electrostatic discharge (ESD).

FIG. 2 diagrammatically illustrates Cut C-C indicated in FIG. 1 passing through the slot well of the semiconductor device of FIG. 1.

FIG. 3 diagrammatically illustrates a workflow for fabricating the semiconductor device of FIG. 1, by way of a flowchart and cut views after performing successive steps of the workflow.

FIGS. 4A and 4B show: a well mask for forming a slotted well (FIG. 4A); and a well mask for forming a normal (i.e., not slotted) well (FIG. 4B).

FIG. 5 diagrammatically illustrates a cut view of a semiconductor device with a slot well to improve resistance to damage from ESD according to an embodiment which includes a well slot only on a drain side.

FIG. 6 diagrammatically illustrates a cut view of a semiconductor device with a slot well to improve resistance to damage from ESD according to an embodiment which includes a well slot only on a source side.

FIG. 7 diagrammatically illustrates a cut view of a semiconductor device with a slot well to improve resistance to damage from ESD according to an embodiment which includes resist protection oxide.

FIG. 8 diagrammatically illustrates a cut view of metal gate contacts without self-aligned contact.

FIG. 9 diagrammatically illustrates a cut view of metal gate contacts with self-aligned contact.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

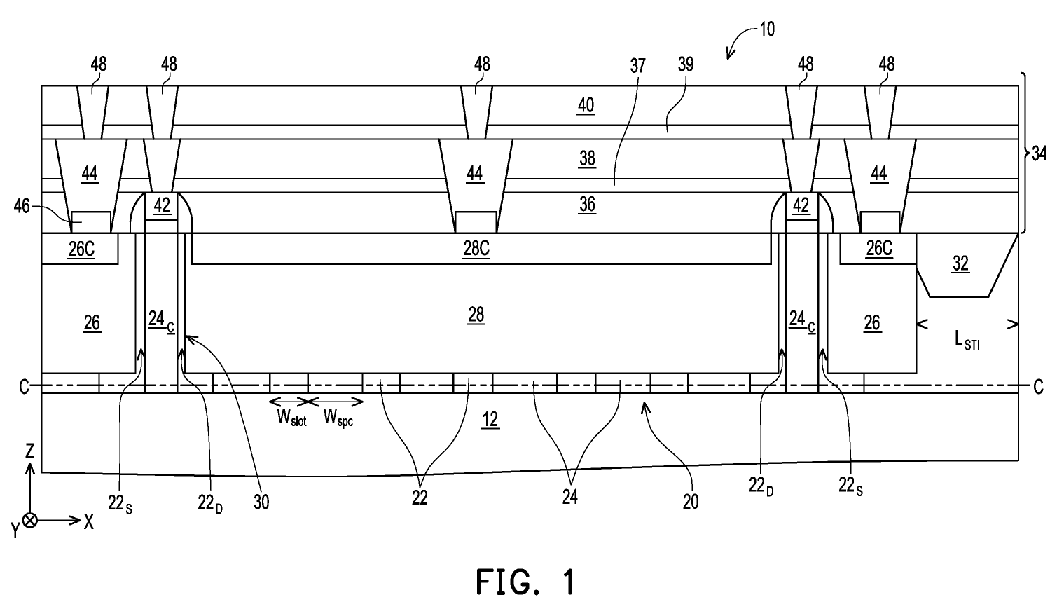

With reference to FIG. 1, a cut view is diagrammatically shown of a semiconductor device 10 formed in a base semiconductor 12. The base semiconductor 12 may be a silicon substrate (e.g., a silicon wafer), a silicon layer (e.g., an epitaxial silicon layer) disposed on a silicon or other substrate or wafer, or the base semiconductor 12 may be the silicon layer of a silicon-on-insulator (SOI) wafer, or so forth. More generally, the base semiconductor 12 may comprise a semiconductor material other than silicon, such as a gallium arsenide (GaAs) substrate. The illustrative semiconductor device 10 includes a transistor disposed in a doped well 20.

As disclosed herein, the doped well 20 is designed to enhance the robustness of the semiconductor device 10 against damage from an electrostatic discharge (ESD). Particularly, the doped well 20 is a slotted well 20 which includes slots 22 having doping a first doping level and slot spaces 24 between the slots having doping of the same type as the slots at a second doping level greater than the first doping level. By “doping of the same type” it is meant that both the slots 22 and the slot spaces 24 are doped P-type; or, alternatively, both the slots 22 and the slot spaces 24 are doped N-type. By way of some nonlimiting examples, if the base semiconductor 12 is silicon and the slots 22 and the slot spaces 24 are doped P-type, some suitable P-type dopants include boron (B), aluminum (Al), gallium (Ga), or indium (In). By way of some nonlimiting examples, if the base semiconductor 12 is silicon and the slots 22 and the slot spaces 24 are doped N-type, some suitable N-type dopants include nitrogen (N), phosphorous (P), arsenic (As), or antimony (Sb). Again, these are nonlimiting examples.

The transistor of FIG. 1 includes a source region 26 disposed in the slotted well 20, a drain region 28, disposed in the slotted well, and a channel 30 which is interposed between the source region 26 and the drain region 28. The channel 30 comprises a portion of the slotted well 20 including at least one slot space 24_{C}. In the illustrative embodiment of FIG. 1, the channel 30 further includes (at least a portion of) a slot 22_{S}adjacent the source region 26, and (at least a portion of) a slot 22_{D}adjacent the drain region 28. Note that the transistor shown in FIG. 1 is a common source transistor that functionally provides two transistor devices, with each transistor device having its own source 26, but with the two transistor devices sharing the common drain 28 of the common source transistor. The source and drain regions 26 and 28 have doping of an opposite doping type compared with the well 20. That is, if the slots 22 and slot spaces 24 of the well 20 are doped P-type then the source region 26 and drain region 28 are both N-type; or, if the slots 22 and slot spaces 24 of the well 20 are doped N-type then the source region 26 and drain region 28 are both P-type. Moreover, the source region 26 and drain region 28 are both doped more heavily than the slots 22 and slot spaces 24 of the well 20. To facilitate electrical contact to the source and drain regions 26 and 28, corresponding more heavily doped source and drain contacts 26C and 28C (e.g., doped P+ or N+) are disposed on the respective source and drain regions 26 and 28.

The illustrative transistor of FIG. 1 further includes isolation regions which in the illustrative example are shallow trench isolation (STI) regions 32, and a metallization stack 34 including one or more interlayer dielectric (ILD) layers (illustrative ILD0 36, dielectric1 layer 37, ILD1 38, dielectric2 layer 39, and ILD2 40) with MG (metal gate) contacts 42 to a gate oxide disposed on the channel 30, and MD contacts 44 to the source 26 and drain 28. The illustrative MG contacts 42 incorporate silicide interfacial layers 46. Vias 48 passing through the ILD2 layer 40 provide connection to upper layers (not shown) of the metallization stack 34.

For convenience in describing the layout of the semiconductor device 10, a Cartesian X-Y-Z coordinate system is indicated in FIG. 1 (and in a number of other drawings herein). Without loss of generality, for convenience of notation, the channel direction is the indicated X-direction. The channel direction is the direction of current flow through the channel between the source 26 and drain 28. Put another way, the source 26 and drain 28 are spaced apart along the X-direction (i.e., channel direction), with the channel 30 interposed between the source region 26 and the drain region 28. The various dielectric layers 36, 37, 38, 39, and 40 are stacked along the Z-direction (which is orthogonal to the X-direction), and the Y-direction is orthogonal to both the X-direction and the Z-direction.

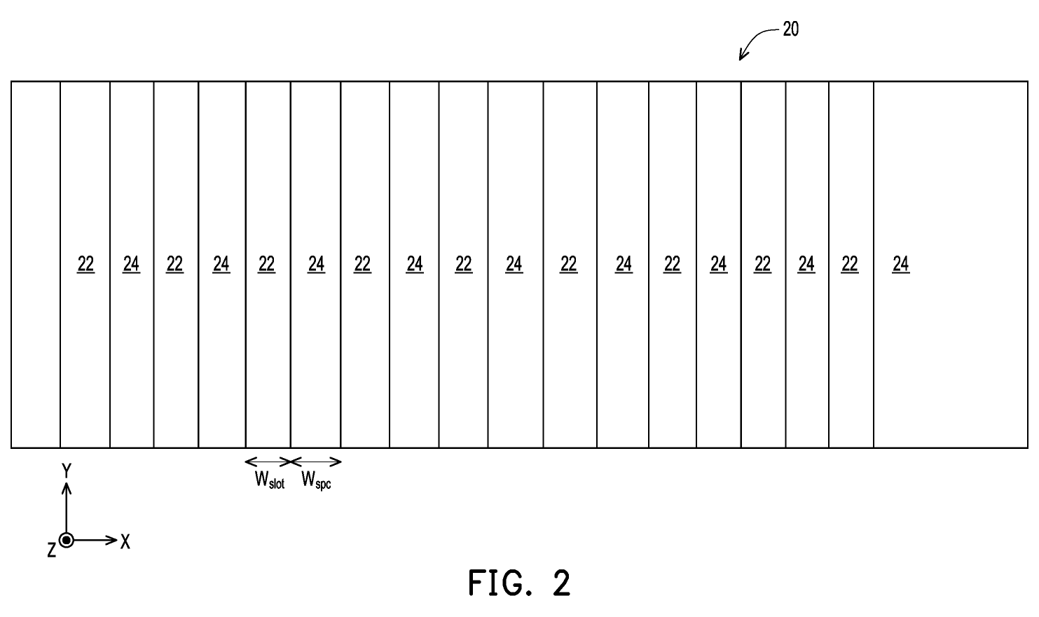

With continuing reference to FIG. 1 and with further reference to FIG. 2 which diagrammatically illustrates Cut C-C indicated in FIG. 1 passing through the slot well 20, the slots 22 and slot spaces 24 alternate along the X-direction. Each slot 22 has uniform doping in the Y-Z directions, and likewise each slot space 24 has uniform doping in the Y-Z directions.

Some transistor metrics according to some nonlimiting examples may include the following. A width Wₛₗₒₜ of the slots 22 along the X-direction may be in a range of between 0.1 micron and 0.5 micron, and a width W_{spc} of the slot spaces 24 along the X-direction may be in a range of between 0.1 micron and 0.5 micron. These ranges are motivated by considerations of providing a suitable reduction in effective well doping to provide the desired ESD resistance without source/drain punch, and ease of lithographic fabrication. A number (i.e., count) of the slots 22 along the drain 28 can be one, two, three, four, five, or more (illustrative seven slots 22 along the drain 28 in the X-direction in FIG. 1). A number (i.e., count) of the slots 22 along the source 26 can be one, two, three, four, five, or more (illustrative one slot 22 along the source 26 in the X-direction in FIG. 1). The STI 32 may have a length L_{STI} along the X-direction in a range of between 0.1 micron and 10 microns. However, in some embodiments the STI 32 may be omitted altogether. The device area for the common source transistor may be in a range of between 30 square microns and 1000 square microns. The length along the X-direction (i.e., along the channel direction) of the MG contacts 42 may be in a range of between 10 nanometers and 10,000 nanometers. The width along the Y-direction (i.e., transverse to the channel direction) of the MG contacts 42 may be in a range of between 1 micron and 100 microns. The MG contacts 42 may, for example, be metal gates or a polycrystalline silicon (i.e., polysilicon) gates. These are merely some nonlimiting examples, and dimensions outside these respective ranges are also contemplated. Moreover, while the illustrative common drain transistor is a planar MOSFET, i.e., a planar metal-oxide-semiconductor (MOS) field effect transistor (FET), the disclosed approaches for enhancing electrostatic discharge (ESD) protection can be employed with other types of transistors, such as other types of planar transistors (e.g., MOSFETs without a common drain), FinFETs, nanosheet FETs, nanowire FETs, or so forth, as well as for semiconductor devices other than transistors, such as diodes.

Semiconductor devices, which may include ESD devices such as input/output (I/O) MOSFETs, in some technologies exhibit undesirably poor ESD performance. For example, a MOSFET tested using a HBM test circuit (e.g., comprising an RC circuit with a high voltage source and one or more switches to simulate a transient ESD event from contact with a charged person) may exhibit destructive failure due to the ESD at substantially zero kilovolts. By comparison, some applications call for the MOSFET to be resistant to an ESD of up to at least 2 kilovolts.

Without being limited to any particular theory of operation, it is believed that the poor ESD performance of some semiconductor devices is due to high surface electric field during the electrostatic discharge. The mechanism is believed to be related to high dopant concentration of the well and the source and drain. The slotted well 20 disclosed herein advantageously enhances ESD performance by reducing the surface electric field at the interface between the (slotted) well 20 and the drain 28 (or source 26). As the slotted well 20 is discontinuous due to the alternation of the lower-doped slots 22 and the higher-doped slot spaces 24, there is alternation of light and heavy dopant concentration. This reduces the surface electric field and enhances robustness against ESD events, for example in some embodiments providing a MOSFET that can pass an HBM test requiring the MOSFET to be resistant to an ESD of up to at least 2 kilovolts.

A further advantage is that, as will be discussed in the fabrication sequence hereinbelow, the slotted well 20 providing enhanced ESD robustness can be readily integrated with a workflow that concurrently fabricates other semiconductor devices (e.g., other MOSFETs) in wells that are not slotted. Put another way, an integrated circuit (IC) may include both semiconductor devices 10 fabricated in (i.e., disposed in) slotted wells 20, and also other semiconductor devices fabricated in (i.e., disposed in) wells that do not include slots 22. The modification of the workflow can be as minimal as modifying the well masks for those semiconductor devices that should be optimized for robustness against ESD events. This can be advantageous because a higher-doped well can provide enhanced isolation for the semiconductor device, which can be beneficial for some semiconductor devices and/or some portions of the IC that may be sensitive to poor isolation. At the same time, the semiconductor devices 10 fabricated in slotted wells 20 provide the desired ESD protection. For example, MOSFETs used for input/output (I/O) of signals to/from the IC may be semiconductor devices 10 fabricated in slotted wells 20 such as is shown in FIG. 1. Since these I/O MOSFETs interface with the external environment (i.e., external to the IC), they are prone to being contacted by a human (e.g., finger touch) or other source of electrostatic discharge. Hence, having these I/O MOSFETs be robust against ESD events provides ESD protection for the IC as a whole.

Still yet a further advantage is that, by placing a slot of the slotted well in the channel adjacent the source (and/or drain), the hot carrier effect can be reduced. The hot carrier effect can arise due to excessively high electric fields, which can be prone to form in the channel proximate to the source or drain. The disclosed reduction of hot carrier effect beneficially reduces hot carrier-induced device degradation of the transistor or other semiconductor device over time. As previously noted, in the illustrative example of FIG. 1, the channel 30 includes the (at least portion of) slot 22_{S} adjacent the source region 26, and the (at least portion of) slot 22_{D} adjacent the drain region 28. The (at least portion of) slot 22_{S} adjacent the source region 26 reduces the electric field in the vicinity of the source/channel interface, thus advantageously reducing the hot carrier effect at the source/channel interface. Likewise, the (at least portion of) slot 22_{D} adjacent the drain region 28 reduces the electric field in the vicinity of the drain/channel interface, thus advantageously reducing the hot carrier effect at the drain/channel interface.

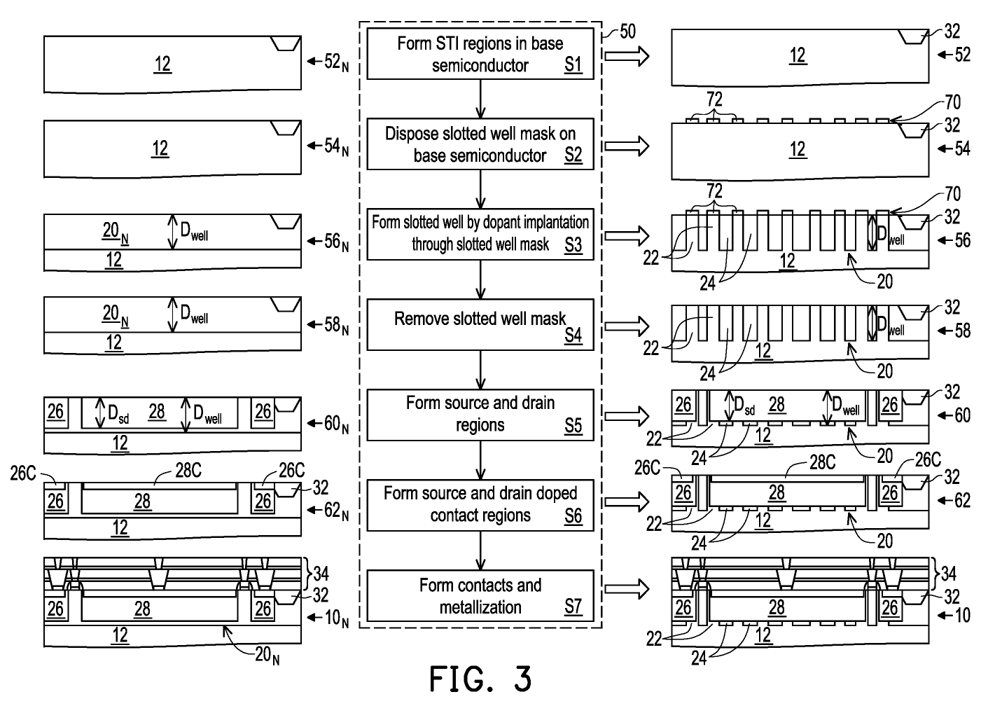

With reference now to FIG. 3, a workflow for fabricating the semiconductor device 10 of FIG. 1 is diagrammatically illustrated. The central portion of FIG. 1 shows a flowchart of a workflow 50. The righthand side of FIG. 3 shows cut views after performing successive steps of the workflow 50. The workflow includes steps S1, S2, S3, S4, S5, S6, and S7 with corresponding respective cut views 52, 54, 56, 58, 60, 62, and 64. Also shown on the lefthand side of FIG. 3 are selected corresponding cut views after performing successive steps for fabricating a semiconductor device in a “normal” (i.e., non-slotted) well 20_{N}, to illustrate how a single IC fabrication process can fabricate both semiconductor devices 10 in slotted wells 20 (corresponding to FIG. 1) and also semiconductor devices in normal wells 20_{N}.

The workflow 50 starts with an operation S1 comprising forming the STI regions 32 in the base semiconductor 12. As previously noted, the base semiconductor 12 may be a silicon wafer (or a silicon layer deposited on such a wafer), an SOI wafer, a GaAs wafer, or so forth. The base semiconductor 12 in some embodiments may be doped by implantation with an implant dosage in a range of between 1x10⁶ cm⁻² and 5x10¹⁰ cm⁻², although dosages outside this nonlimiting example range are also contemplated. Furthermore, in some embodiments the base semiconductor 12 may have doping formed in another way – for example, if the base semiconductor 12 is a silicon wafer then the doping of the base semiconductor 12 may correspond to the doping of the silicon wafer. The STI formation entails trench etching and filling with an oxide or other insulating material. As previously noted, another type of isolation may be used in place of the STI, or in some embodiments the operation S1 forming the isolation may be omitted entirely. As shown in the righthand side of FIG. 1, this results in a structure diagrammatically shown by cut view 52. As indicated by cut view 52_{N} shown on the lefthand side of FIG. 3, fabrication of a semiconductor device in a normal well also includes this (optional) isolation formation processing S1.

In an operation S2, as shown in a cut view 54, a slotted well mask 70 is formed on (the surface of) the base semiconductor 12 in the area where the well 20 is destined to be fabricated. The slotted well mask 70 comprises a plurality of mutually parallel masking strips 72 which correspond to the slots 22 of the slotted well 20 being fabricated. That is, each masking strip 72 has the same dimensions in the X-Y plane as the corresponding slot 22. The plurality of mutually parallel masking strips 72 (i.e., masking regions 72) are spaced apart along the X or channel direction in the example of FIG. 3.The operation S2 forms the slotted well mask 70 using a lithographic process such as photolithography, nano imprint lithography (NIL), or the like. The slotted well mask 70 may comprise a lithographically patterned photoresist, a lithographically patterned hard mask (e.g., comprising a dielectric material that is resistant to a subsequent dopant implant step S3), a combination thereof, or so forth.

By comparison, a slotted well mask is not formed on (the surface of) the base semiconductor 12 in the area where a normal well 20_{N} is destined to be fabricated. Hence, a cut view 54_{N} shown on the lefthand side of FIG. 3 after the operation S2 is identical with the cut view 52_{N}, as no slotted well mask is formed.

In an operation S3, as shown in a cut view 56, the slotted well 20 is formed by dopant implantation through the slotted well mask 70. Due to the presence of the masking strips 72 of the slotted well mask 70, the dopant implantation of operation S3 does not implant dopant in the slots 22 of the base semiconductor 12 located underneath the mutually parallel masking strips 72 of the slotted well mask 70. Rather, the dopant implants only in the spaces between the masking strips 72 – these spaces correspond to the slot spaces 24. The dopant implanted in operation S3 is of the same type as the dopant type of the base semiconductor 12 – hence, the dopant implant operation S3 increases the doping concentration in the slot spaces 24 relative to the slots 22. In some nonlimiting examples, the dopant implantation operation S3 implants a dopant dosage in a dose range of between 1x10¹¹ cm⁻² and 5x10¹⁵ cm⁻². In some embodiments, a ratio of the dopant concentration in the slot spaces 24 to the dopant concentration in the slots 22 is in a range between 10⁴ and 10⁷. Again, these are merely some nonlimiting examples. The slotted well 20 has a well depth denoted D_{well} in the cut view 56.

By comparison, with reference to cut view 56_{N} shown on the lefthand side of FIG. 3, since a slotted well mask is not present on (the surface of) the base semiconductor 12 in the area where a normal well 20_{N} is destined to be fabricated, the entire area of the normal well 20_{N} is doped, e.g., in the aforementioned nonlimiting example dose range of between 1x10¹¹ cm⁻² and 5x10¹⁵ cm⁻². This produces the normal well 20_{N} shown in the cut view 56_{N}, which has no slots. The normal well 20_{N} has the same well depth D_{well} as the slotted well 20.

Viewed another way, the slots 22 of the slotted well 20 provide a reduced effective doping concentration for the slotted well 20, when compared with the normal well 20_{N}. This reduced effective doping concentration for the slotted well 20 reduces the surface electric field at the interface between the (slotted) well 20 and the drain 28 (or source 26), and thereby enhances robustness of the transistor 10 against ESD events.

In an operation S4, as shown in a cut view 58, the slotted well mask 70 is removed, using processing suitable for the type(s) of material making up the slotted well mask 70. For example, if the slotted well mask 70 is entirely comprised of photoresist, then the operation S4 may employ a photoresist stripping process. If the slotted well mask 70 is made of a dielectric hard mask, then an etchant that preferentially etches the dielectric material over the material of the base semiconductor 12 may be used.

By comparison, with reference to cut view 58_{N} shown on the lefthand side of FIG. 3, since a slotted well mask was not formed in the operation S2 on (the surface of) the base semiconductor 12 in the area where the normal well 20_{N} was fabricated, a cut view 58_{N} is identical with the previous cut view 56_{N} for the semiconductor device being fabricated in the normal well 20_{N}.

In an operation S5, the source and drain regions 26 and 28 are formed, as shown in a corresponding cut view 60. In one example approach, the operation S5 entails dopant implantation using a mask to define the source and drain areas, followed by mask removal and a thermal anneal; however, other dopant methods are contemplated. As seen in corresponding cut view 60_{N} on the lefthand side of FIG. 3 for the semiconductor device being fabricated in the normal well 20_{N}, the result of operation S5 is identical for the semiconductor device being fabricated in the normal well 20_{N}, except that the normal well 20_{N} underlying the source and drain regions 26 and 28 does not include slots 22. The source and drain regions 26 and 28 have depth D_{sd} indicated in the respective slotted and normal (i.e., not slotted) cut views 60 and 60_{N} which is less than the well depth D_{well} of the slotted well 20 (and of the normal well 20_{N}) – consequently, the lower portion of the slotted well 20 (and the normal well 20_{N}) remains underneath the source and drain regions 26 and 28. As the source and drain regions delineate the semiconductor device in this illustrative example of a transistor, this can alternatively be stated as the semiconductor device (e.g., transistor) has a device depth D_{sd} that is less than the well depth D_{well} of the slotted well 20.

In an operation S6, the source and drain contacts 26C and 28C are formed on the respective source and drain regions 26 and 28, e.g., by dopant diffusion, dopant implantation, or the like. This results in a cut view 62 shown on the righthand side of FIG. 3. As seen in corresponding cut view 62_{N} on the lefthand side of FIG. 3 for the semiconductor device being fabricated in the normal well 20_{N}, the result of operation S6 is identical for the semiconductor device being fabricated in the normal well 20_{N}, except that again the normal well 20_{N} underlying the under-fabrication transistor does not include slots 22.

In an operation S7, further processing forms the metallization 34 and contacts 42, 44, vias 48, and so forth. The operation S7 (or at least a portion thereof) is sometimes referred to as back end-of-line (BEOL) processing. The result is the cut view of the semiconductor device 10 corresponding to FIG. 1. As seen in corresponding cut view 10_{N} on the lefthand side of FIG. 3 for the semiconductor device fabricated in the normal well 20_{N}, the result of operation S7 is again identical except that the normal well 20_{N} underlying the transistor does not include slots 22.

Comparing the fabrication of the semiconductor device 10 in the slotted well 20 (righthand side of FIG. 3) with the fabrication of the semiconductor device in the normal well 20_{N} (lefthand side of FIG. 3), it is seen that the differences in the two fabrication workflows are the operation S2 (disposing the slotted well mask 70) and operation S4 (removing same) which are included in the former workflow but omitted in the latter workflow.

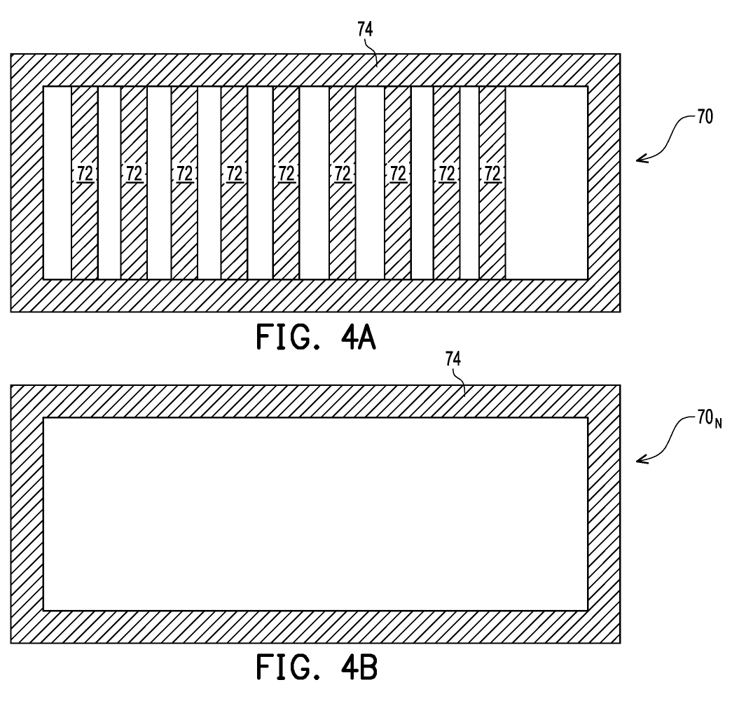

With reference now to FIGS. 4A and 4B, however, in some nonlimiting example embodiments, the formation of both the slotted well 20 and the normal well 20_{N} utilize a respective well area mask 74 to define the areas of the respective slotted wells 20 and the respective normal wells 20_{N}. Hence, in such embodiments, as shown in FIG. 4A the slotted well mask 70 can comprise the combination of this well area mask 74 and the mutually parallel masking strips 72 that correspond to the slots 22 of the slotted well 20. By contrast, as shown in FIG. 4B, a mask 70_{N} used to form the “normal” (i.e., non-slotted) well 20_{N} includes the well area mask 74, but does not include the masking strips 72. Hence, in such embodiments, the only difference between the fabrication of the semiconductor device 10 in the slotted well 20 (righthand side of FIG. 3) and the fabrication of the semiconductor device in the normal well 20_{N} (lefthand side of FIG. 3) is the inclusion of the masking strips 72 in the mask 70 used to form the slotted well 20, versus the omission of such masking strips in the mask 70_{N} used to form the normal well 20_{N}. This is advantageous, because it follows that the ESD-resistant transistors (e.g., FIG. 1 and righthand side of FIG. 3) and the “normal” transistors (e.g., lefthand side of FIG. 3) can be fabricated in a single integrated circuit (IC) workflow with suitable selection of the slotted well mask 70 or normal well mask 70_{N} depending on whether a device is to be optimized for robustness against ESD events or for enhanced isolation of the transistor.

A further advantage of the slotted well 20 is that, by aligning slots at one or both edges of the channel 30 adjacent the source 26 and/or drain 28, the hot carrier effect can be reduced. The hot carrier effect can arise due to excessively high electric fields, which can be prone to form in the channel 30 proximate to the source 26 or drain 28. The disclosed reduction of hot carrier effect beneficially reduces hot carrier-induced device degradation of the transistor or other semiconductor device over time. In the example of FIG. 1, the (at least portion of) slot 22_{S} adjacent the source region 26 reduces the hot carrier effect in the vicinity of the source/channel interface, and likewise the (at least portion of) slot 22_{D} adjacent the drain region 28 reduces the hot carrier effect in the vicinity of the drain/channel interface.

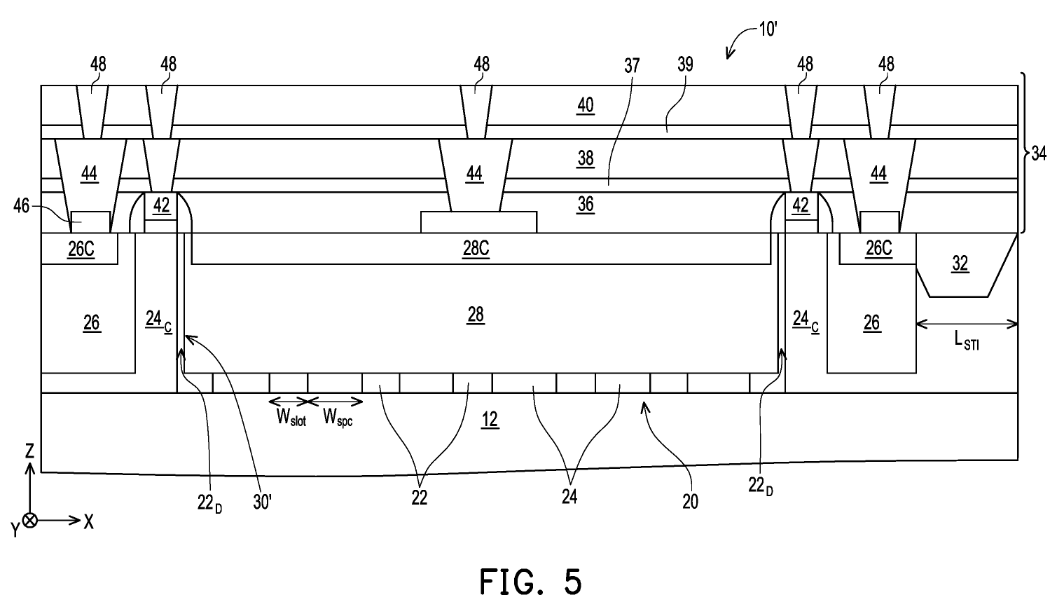

With reference to FIG. 5, a variant semiconductor device 10’ includes the features 12, 20, 22, 24, 26, 26C, 28, 28C, 32, 34, 36, 37, 38, 39, 40, 42, 44, 46, 48 as already described with reference to the semiconductor device 10 of the embodiment of FIG. 1. The variant semiconductor device 10’ of FIG. 5 differs from that of FIG. 1 in that the variant semiconductor device 10’ of FIG. 5 has a channel 30’ which includes only the (at least portion of) slot 22_{D} adjacent the drain region 28, but not the (at least portion of) slot 22_{S} adjacent the source region 26.

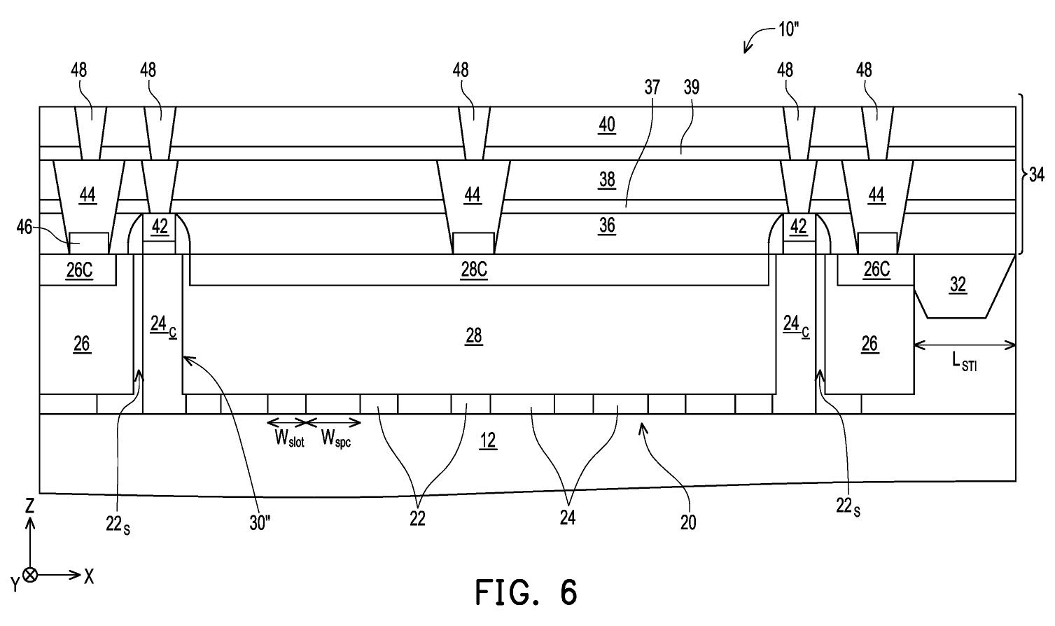

With reference to FIG. 6, a variant semiconductor device 10’’ includes the features 12, 20, 22, 24, 26, 26C, 28, 28C, 32, 34, 36, 37, 38, 39, 40, 42, 44, 46, 48 as already described with reference to the semiconductor device 10 of the embodiment of FIG. 1. The variant semiconductor device 10’’ of FIG. 6 differs from that of FIG. 1 in that the variant semiconductor device 10’’ of FIG. 6 has a channel 30’’ which includes only the (at least portion of) slot 22_{S} adjacent the source region 26, but not the (at least portion of) slot 22_{D} adjacent the drain region 28.

Although not shown, it is also contemplated in a further variant embodiment to omit both the (at least portion of) slot 22_{S} adjacent the source region 26 and the (at least portion of) slot 22_{D} adjacent the drain region 28. In this case, the channel would consist entirely of the slot space 24_{C}.

The disclosed approaches for enhancing ESD robustness (and optionally also reducing hot carrier effect degradation) can be employed with various types of transistors (e.g., various planar transistors, FinFETs, nanosheet FETs, nanowire FETs, or so forth), and even more broadly with other types of semiconductor devices (e.g., diodes). In the following, and by way of nonlimiting broadening illustration rather than limitation, some further variants are described.

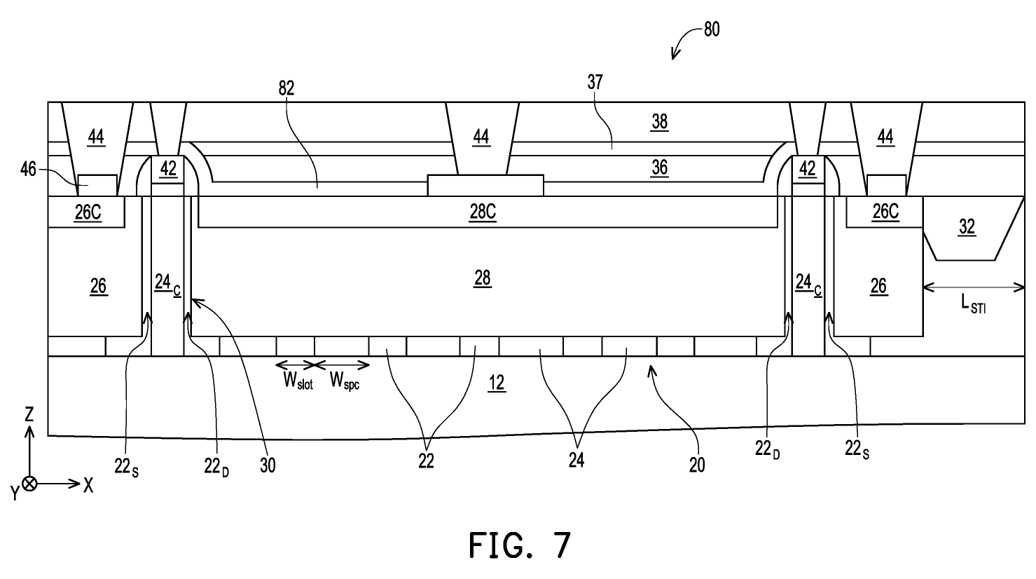

FIG. 7 diagrammatically illustrates a cut view of a semiconductor device 80 with a slot well 20 to improve resistance to damage from ESD according to an embodiment which includes resist protection oxide (RPO) 82. The semiconductor device 80 of FIG. 7 includes the features 12, 20, 22, 24, 26, 26C, 28, 28C, 30, 32, 36, 37, 38, 42, 44, and 46 as already described with reference to the semiconductor device 10 of the embodiment of FIG. 1. The semiconductor device 80 of FIG. 7 further includes the RPO 82, which provides certain benefits such as blocking silicide formation where the RPO is deposited (i.e., during the formation of the silicide regions 46), and reducing the upper surface electric field from drain to gate. The illustrative example of FIG. 7 includes the channel 30 with both the (at least portion of) slot 22_{S} adjacent the source region 26, and the (at least portion of) slot 22_{D} adjacent the drain region 28; however, the design of FIG. 7 could alternatively employ the channel 30’ of FIG. 5 or the channel 30’’ of FIG. 6; or both features 22_{S} and 22_{D} could be omitted.

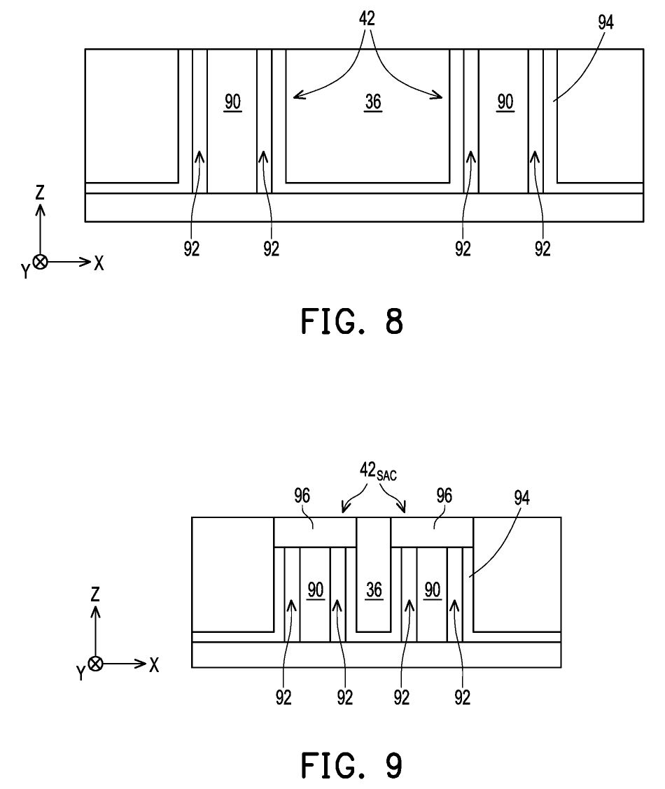

FIG. 8 diagrammatically illustrates a cut view of the metal gate (MG) contacts 42 without self-aligned contact. Each MG contact 42 is formed in ILD 36, and includes a metal gate (MG) 90, for example comprising a metal such as tungsten, titanium nitride (TiN), tantalum nitride (TaN), ruthenium, or the like. Each MG 90 is surrounded by spacers 92 suitably comprising silicon nitride (SiN), silicon carbon nitride (SiCN), silicon carbon oxynitride (SiCON), or the like. A bottom etch stop layer 94 is employed to control etching. A process flow for formation of the MG contact 42 is deposition of the metal forming the MG 90 followed by chemical mechanical polishing (CMP), followed by metal gate etch back, and spacer pull back.

FIG. 9 diagrammatically illustrates a cut view of the metal gate (MG) contacts 42_{SAC} with self-aligned contact (SAC). Each MG contact 42_{SAC} is formed in ILD 36, and includes a metal gate (MG) 90, for example comprising a metal such as tungsten, TiN, TaN, ruthenium, or the like. Each MG 90 is surrounded by spacers 92 suitably comprising SiN, SiCN, SiCON, or the like. A bottom etch stop layer 94 is employed to control etching. A process flow for formation of the MG contact with SAC 42_{SAC} is deposition of the metal forming the MG 90 followed by chemical mechanical polishing (CMP), followed by metal gate etch back, and spacer pull back, deposition of a SEC dielectric material 96, and CMP of the SAC dielectric material.

It is again noted that the variant embodiments and aspects of FIGS. 7, 8, and 9 are presented by way of nonlimiting broadening illustration rather than limitation, and any given embodiment may include one or more of the features of these embodiments, or none of the features of these embodiments.

In the following, some further embodiments are described.

In a nonlimiting illustrative embodiment, a semiconductor device fabrication method includes: disposing a slotted well mask on a base semiconductor doped at a first doping type; performing dopant implantation of the first doping type through the well slot mask to form a slotted well in the base semiconductor; removing the slotted well mask; and forming a semiconductor device in the slotted well.

In a nonlimiting illustrative embodiment, a method of fabricating a transistor includes: disposing a slotted well mask comprising mutually parallel masking strips on a base semiconductor; performing well dopant implantation through the slotted well mask to form a slotted well in the base semiconductor, wherein the masking strips block the well dopant implantation into slots of the slotted well which are located underneath the masking strips; and forming source and drain regions of the transistor in the slotted well. The source and drain regions are spaced apart by a channel comprising a portion of the slotted well.

In a nonlimiting illustrative embodiment, a semiconductor device includes a slotted well and a transistor disposed in the slotted well. The slotted well includes slots having doping a first doping level and slot spaces between the slots having doping of a same type as the slots at a second doping level greater than the first doping level.

In a nonlimiting illustrative embodiment, a semiconductor device includes a slotted well and a transistor disposed in the slotted well. The slotted well includes slots having doping a first doping level and slot spaces between the slots having doping of a same type as the slots at a second doping level greater than the first doping level. The transistor includes a source region disposed in the slotted well, and a drain region disposed in the slotted well. A channel is interposed between the source region and the drain region. The channel comprises a portion of the slotted well including at least one slot space. Optionally, the channel may further comprise a slot adjacent the source region and/or a slot adjacent the drain region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device fabrication method comprising:
disposing a slotted well mask on a base semiconductor doped at a first doping type;
performing dopant implantation of the first doping type through the well slot mask to form a slotted well in the base semiconductor;
removing the slotted well mask; and
forming a semiconductor device in the slotted well.

2. The semiconductor device fabrication method of claim 1, wherein:
the slotted well has a well depth; and
the semiconductor device has a device depth that is less than the well depth.

3. The semiconductor device fabrication method of claim 1, wherein:
the slotted well mask comprises a plurality of mutually parallel masking strips; and
the dopant implantation to form a slotted well in the base semiconductor does not implant the first doping type in slots of the base semiconductor located underneath the mutually parallel masking strips of the slotted well mask.

4. The semiconductor device fabrication method of claim 3, wherein:
the slots have widths of between 0.1 micron and 0.5 micron; and
slot spaces between adjacent slots have widths of between 0.1 micron and 0.5 micron.

5. The semiconductor device fabrication method of claim 1, wherein the forming of the semiconductor device in the slotted well comprises:
forming source and drain regions of a second doping type opposite the first doping type in the slotted well;
forming source and drain contact regions in the source and drain regions.

6. The semiconductor device fabrication method of claim 5, further comprising forming a resist protection oxide (RPO) on the drain region.

7. The semiconductor device fabrication method of claim 5, wherein one of:
the first doping type is P-type and the second doping type is N-type; or
the first doping type is N-type and the second doping type is P-type.

8. The semiconductor device fabrication method of claim 1, wherein the semiconductor device comprises a transistor.

9. A method of fabricating a transistor, the method comprising:
disposing a slotted well mask comprising mutually parallel masking strips on a base semiconductor;
performing well dopant implantation through the slotted well mask to form a slotted well in the base semiconductor, wherein the masking strips block the well dopant implantation into slots of the slotted well which are located underneath the masking strips; and
forming source and drain regions of the transistor in the slotted well, the source and drain regions being spaced apart by a channel comprising a portion of the slotted well.

10. The transistor fabrication method of claim 9, wherein the channel includes at least a portion of a slot adjacent the source region and at least a portion of a slot adjacent the drain region.

11. The transistor fabrication method of claim 9, wherein the channel includes at least a portion of a slot adjacent the source region.

12. The transistor fabrication method of claim 9, wherein the channel includes at least a portion of a slot adjacent the drain region.

13. The transistor fabrication method of claim 9, wherein the transistor is a common source transistor including two source regions and one drain region.

14. The transistor fabrication method of claim 9, wherein:
the slotted well has a well depth; and
the source and drain regions have a source/drain depth that is less than the well depth.

15. The transistor fabrication method of claim 9, further comprising forming a resist protection oxide (RPO) on the drain region.

16. The transistor fabrication method of claim 9, further comprising:
disposing a well area mask not including mutually parallel masking strips on the base semiconductor;
performing well dopant implantation to form a well without slots in an area of the base semiconductor defined by the well area mask; and
forming source and drain regions of a second transistor in the well without slots, the source and drain regions of the second transistor being spaced apart by a channel comprising a portion of the well without slots.

17. A semiconductor device comprising:
a slotted well comprising slots having doping a first doping level and slot spaces between the slots having doping of a same type as the slots at a second doping level greater than the first doping level; and
a transistor disposed in the slotted well.

18. A semiconductor device of claim 17, wherein the transistor includes:
a source region disposed in the slotted well; and
a drain region disposed in the slotted well;
wherein a channel is interposed between the source region and the drain region, the channel comprising a portion of the slotted well including at least one slot space.

19. The semiconductor device of claim 18, wherein the channel further comprises a slot adjacent the source region and/or a slot adjacent the drain region.

20. A semiconductor device of claim 18, wherein one of:
the slots and slot spaces of the slotted well are P-type, and the source region and drain region are N-type; or
the slots and slot spaces of the slotted well are N-type, and the source region and drain region are P-type.
